(19) United States
(12) Patent Application Publication
(10) Pub. No.: US 2015/0153403 A1
(43) Pub. Date: Jun. 4, 2015

(54) DETECTION FIXTURE FOR CONNECTOR

(71) Applicants: Fu Tai Hua Industry (Shenzhen) Co., Ltd., Shenzhen (CN); HON HAI PRECISION INDUSTRY CO., LTD., New Taipei (TW)

(72) Inventor: JU-LAN HAO, Shenzhen (CN)

(21) Appl. No.: 14/524,551

(22) Filed: Oct. 27, 2014

(30) Foreign Application Priority Data
Nov. 29, 2013 (CN) 201310624332.2

(51) Int. Cl. G01R 31/04; G01R 1/073

(52) U.S. Cl. CPC G01R 31/04; G01R 1/07307

(57) ABSTRACT

A detection fixture for a connector is provided. The fixture includes a first fixing block, a second fixing block fixed on the first fixing block, a probe, a probe cable, a controlling board coupled with the probe cable, and a computer device. The probe is coupled with the prove, includes a first portion fixed to the first fixing block and the second fixing block, and a second portion exposed to the first fixing block and contacting with a plurality of pins of the connector. The probe cable is fixed on the second fixing block and is coupled with the probe. The computer device is coupled with a connector cable of the connector, and is wirelessly coupled with probe.

### CROSS-REFERENCE TO RELATED APPLICATIONS

This application claims priority to Chinese Patent Application No. 201310624332.2 filed on Nov. 29, 2013, the contents of which are incorporated by reference herein.

### FIELD

The present disclosure relates to fixtures and particularly to a detection fixture for a connector.

### BACKGROUND

While testing a connector, a detection fixture for detecting the stability and performance of the connector is needed.

### BRIEF DESCRIPTION OF THE DRAWINGS

FIG. 1 is an isometric view of a detection fixture for a connector.

FIG. 2 is an exploded view of the detection fixture of FIG. 1.

FIG. 3 is an exploded view of the detection fixture of FIG. 1, viewed from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

Embodiments of the present disclosure will be described with reference to the accompanying drawings.

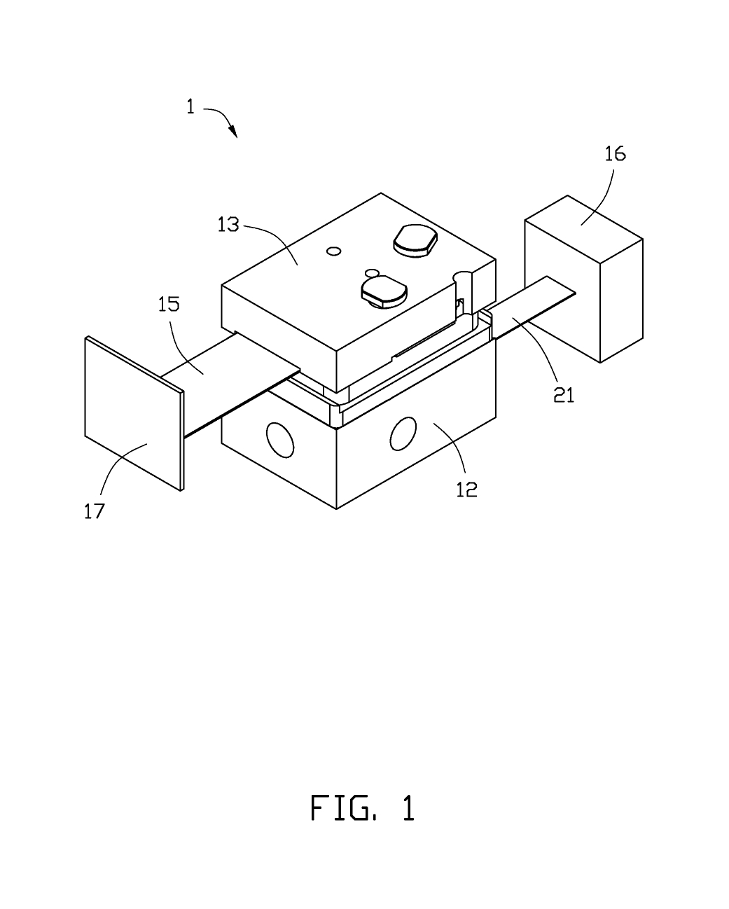

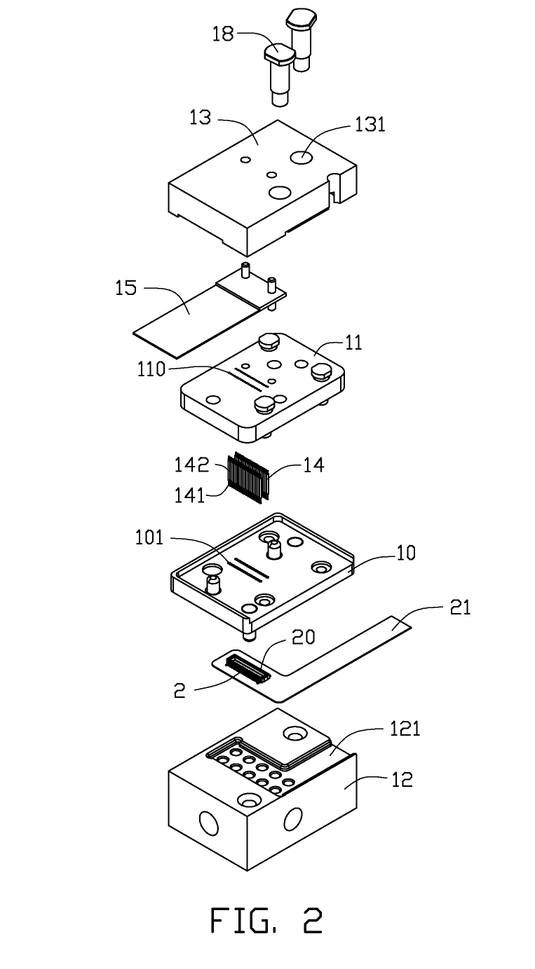

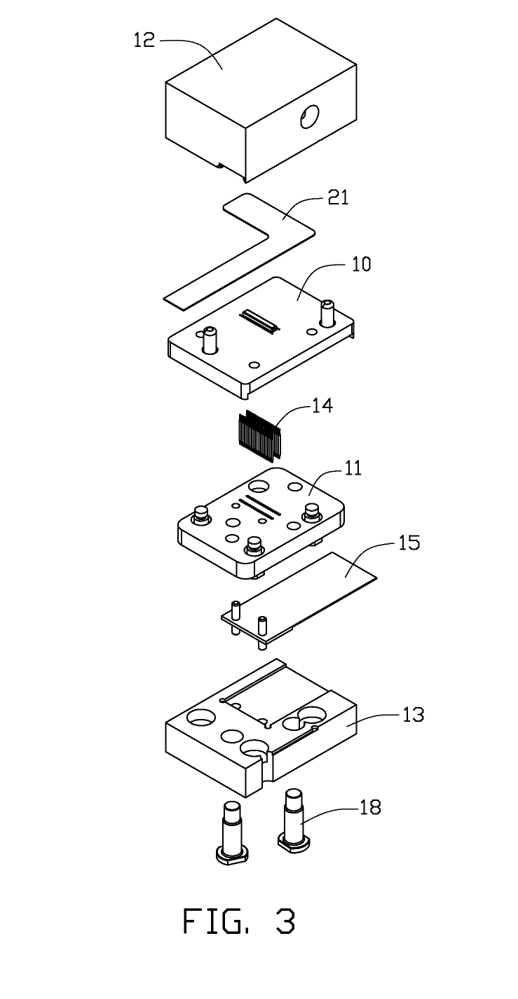

FIG. 1 illustrates a detection fixture 1 for a connector. Referring to FIGS. 2-3, the detection fixture 1 includes a first fixing block 10, a second fixing block 11 fixed on the first fixing block 10, a probe 14, a probe cable 15 fixed on the second fixing block 11 and coupled with the probe 14, a controlling board 17 coupled with the probe cable 15, and a computer device 16 coupled with the connector 2. The computer device 16 is wirelessly coupled with the probe 14. A first portion 142 of the probe 14 is fixed to the first fixing block 10 and the second fixing block 11, and a second portion 141 of the probe 14 is exposed, and contacts a number of pins 20 of the connector 2. The probe cable 15 controls the probe 14 to cause the probe 14 to transmit a first electronic signal to the connector 2 via the number of pins 20, and wirelessly transmit a second electronic signal to the computer device 16 in response to an instruction from the controlling board 17. The connector 2 transmits the first electronic device to the computer device 16 through a connector cable 21. The computer device 16 receives the first electronic device from the connector 2, receives the second electronic signal from the computer device 16, and determines whether the first electronic signal is consistent with the second electronic signal, thereby determining the stability of the performances of the connector 2 according to a comparing result.

In at least one embodiment, the first fixing block 10 defines a pairs of first slots 101, and the second fixing block 11 defines a pairs of second slots 110 aligned with the first slots 101. The first portion 142 of the probe 14 is fixed to the first fixing block 10 and the second fixing block 11 by passing the first slots 101 and the second slots 110.

The detection fixture 1 further includes a third fixing block 12. The third fixing block 12 defines a recessed portion 121. The recessed portion 121 is used to receive the connector 2 and the connector cable 21. In one embodiment, the recessed portion 121 is L shaped.

The detection fixture 1 further includes two screws 18, and a fourth fixing block 13 placed on the second fixing block 11. The fourth fixing block 13 defines two threaded holes 131. The two threaded holes 131 cooperates with the two screws 18 to fix the fourth fixing block 13 on the second fixing block 11. When testing the performance of the connector 2, the connector 2 and the connector cable 21 are placed within the recessed portion 121 of the third fixing block 12. The first fixing block 10 and the second fixing block 11 are placed on the third fixing block 12 to make the second portion 141 of the probe 14 contact with the pins 20 of the connector 2. The probe cable 15 controls the probe 14 to cause the probe 14 to transmit the first electronic signal to the connector 2 via the number of pins 20, and wirelessly transmit the second electronic signal to the computer device 16 in response to the instruction from the controlling board 17. The connector 2 transmits the first electronic device to the computer device 16 through the connector cable 21. The computer device 16 receives the first electronic signal from the connector 2, receives the second electronic signal from the computer device 16, and determines whether the first electronic signal is consistent with the second electronic signal, thereby determining the stability of the performances of the connector 2 according to a comparing result.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A detection fixture for a connector, the detection fixture comprising:
a first fixing block;
a second fixing block fixed on the first fixing block;
a probe comprising a first portion fixed to the first fixing block and the second fixing block, and a second portion exposed to the first fixing block and configured to contact a plurality of pins of the connector;
a probe cable coupled with the probe and fixed to the second fixing block;
a controlling board coupled to the probe cable; and
a computer device connected to a connector cable of the connector, and wirelessly coupled with the probe;
wherein the probe cable is configured to control the probe to cause the probe to transmit a first electronic signal to the connector via the second portion and the plurality of pins, and wirelessly transmit a second electronic device to the computer device in response to an instruction from the controlling board,
the computer device is configured to receive the first electronic signal from the connector via the connector cable, receive the second electronic signal from the probe, and determine whether the first electronic signal is consistent with the second electronic signal.

2. The detection fixture as described in claim 1, further comprising:
a third fixing block defining a recessed portion for receiving the connector and the connector cable.

3. The detection fixture as described in claim 2, wherein the recessed portion is L shaped.

4. The detection fixture as described in claim 1, further comprising:
a fourth fixing block fixed on the second fixing block, and configured to fix the probe cable on the second fixing block.

5. The detection fixture as described in claim 4, further comprising:
two screws; and
two threaded holes defined in the fourth fixing block, and cooperating with the two screws to fix the fourth fixing block on the second fixing block.

6. The detection fixture as described in claim 1, wherein the first fixing block defines a pair of first slots, the second fixing block defines a pair of second slots aligned with the first slots, the first portion of the probe is fixed to the first fixing block and the second fixing block by passing the first slots and the second slots.
